(19) United States
(12) Patent Application Publication
(10) Pub. No.: US 2024/0282705 A1
(43) Pub. Date: Aug. 22, 2024

(54) SEMICONDUCTOR MEMORY DEVICE

(71) Applicant: Samsung Electronics Co., Ltd., Suwon-si (KR)

(72) Inventors: Dong Ha SHIN, Suwon-si (KR); Jae Ick SON, Suwon-si (KR)

(73) Assignee: Samsung Electronics Co., Ltd., Suwon-si (KR)

(21) Appl. No.: 18/417,847

(22) Filed: Jan. 19, 2024

(30) Foreign Application Priority Data
Feb. 16, 2023 (KR) 10-2023-0020600

(51) Int. Cl. H01L 23/528; H01L 23/522; H10B 41/10; H10B 41/27; H10B 41/40; H10B 43/10; H10B 43/27; H10B 43/40

(52) U.S. Cl. CPC H01L 23/5283; H01L 23/5226; H10B 41/10; H10B 41/27; H10B 41/40; H10B 43/10; H10B 43/27; H10B 43/40

(57) ABSTRACT

A semiconductor memory device comprising a cell region on a cell substrate, and a peripheral circuit region on a peripheral circuit board connected to the cell region in a bonding manner is provided. Wherein the cell region comprises a plurality of gate electrodes sequentially stacked on a first side of the cell substrate, a first bypass cell contact plug extended in a vertical direction in an extended region connected to the first gate electrode, a normal cell contact plug extended in the vertical direction in the extended region and connected to the second gate electrode, a first metal wiring electrically connected to the first bypass cell contact plug and a second metal wiring on the first metal wiring and electrically connected to the first metal wiring, wherein the second metal wiring is connected with the fourth metal wiring through a first bypass path including a plurality of bonding metal pairs.

### CROSS-REFERENCE TO RELATED APPLICATIONS

This application claims priority under 35 U.S.C. § 119 to Korean Patent Application No. 10-2023-0020600 filed on Feb. 16, 2023 in the Korean Intellectual Property Office, the disclosures of which are incorporated by reference herein in their entireties.

### BACKGROUND

### 1. Field of the Invention

Various example embodiments relate to a semiconductor memory device and an electronic system including the same. More specifically, various example embodiments relate to a semiconductor memory device including memory cells arranged three-dimensionally and an electronic system including the same.

### 2. Description of Conventional Arts

With the demand for semiconductor memory device capable of storing high-capacity of data in electronic system, measures capable of increasing a data storage capacity of the semiconductor memory device are being researched. As one of measures capable of increasing the data storage capacity of the semiconductor memory device, a semiconductor memory device including memory cells arranged three-dimensionally instead of memory cells arranged two-dimensionally has been proposed.

### SUMMARY

Example embodiments of inventive concepts provide a semiconductor memory device in which variations in wiring resistance of word lines decrease.

Example embodiments of inventive concepts provide an electronic system including the semiconductor memory device in which variations in wiring resistance of word lines decrease.

Example embodiments of inventive concepts provide a semiconductor memory device comprising a cell region on a cell substrate, and a peripheral circuit region on a peripheral circuit board and connected to the cell region in a bonding manner, wherein the cell region includes a plurality of gate electrodes sequentially stacked on a first side of the cell substrate, a first bypass cell contact plug extended in a vertical direction in an extended region and connected to a first gate electrode of the plurality of gate electrodes, a normal cell contact plug extended in the vertical direction in the extended region and connected to a second gate electrode of the plurality of gate electrodes, a first metal wiring electrically connected to the first bypass cell contact plug and a second metal wiring on the first metal wiring and electrically connected to the first metal wiring, wherein the peripheral circuit region includes a plurality of circuit elements on the peripheral circuit board, a third metal wiring on a first circuit element of the plurality of circuit elements and electrically connected to the first circuit element and a fourth metal wiring on the third metal wiring and electrically connected to the third metal wiring, wherein the second metal wiring are connected with the fourth metal wiring through a first bypass path including a plurality of bonding metal pairs.

Example embodiments of inventive concepts provide a semiconductor memory device comprising a plurality of gate electrodes stacked on a cell substrate in a vertical direction, a plurality of cell contact plugs in the vertical direction and have one end connected to each of the plurality of gate electrodes, a plurality of first metal wirings on the other end of the cell contact plug and connected to each of the plurality of cell contact plugs, a plurality of second metal wirings on the first metal wirings and each electrically connected to the first metal wirings, a plurality of first bonding metals on the second metal wirings, a plurality of first dummy bonding metals in the same layer as the first bonding metals, a plurality of circuit elements on a peripheral circuit board, a plurality of third metal wirings on the plurality of circuit elements and each connected to the plurality of circuit elements, a plurality of fourth metal wirings on the third metal wirings and each electrically connected to the third metal wirings, a plurality of second bonding metals on the fourth metal wirings, each electrically connected to the fourth metal wiring, and each bonded to the plurality of first bonding metals and a plurality of second dummy bonding metals in the same layer as the second bonding metals, wherein at least one first bonding metal and at least one second bonding metal are electrically connected through the plurality of first dummy bonding metals and the plurality of second dummy bonding metals.

Other aspects of various example embodiments provide a semiconductor memory device comprising a plurality of gate electrodes stacked on a cell substrate in a vertical direction, a plurality of cell contact plugs which extend in the vertical direction and have one end connected to each of the plurality of gate electrodes, a plurality of first metal wirings on the other end of the cell contact plug and connected to each of the plurality of cell contact plugs, a plurality of second metal wirings on the first metal wirings and electrically connected to each of the first metal wirings, a plurality of circuit elements on a peripheral circuit board, a plurality of third metal wirings on the plurality of circuit elements and each connected to the plurality of circuit elements, a plurality of fourth metal wirings on the third metal wirings and each electrically connected to the third metal wirings and a plurality of bonding metal pairs on the second and fourth metal wirings, wherein each wiring resistance electrically connected from the plurality of cell contact plugs to the plurality of circuit elements is uniform.

However, aspects of various example embodiments are not restricted to the one set forth herein. The above and other example embodiments will become more apparent to one of ordinary skill in the art to which the present example embodiments pertains by referencing the detailed description of the inventive concepts given below.

### BRIEF DESCRIPTION OF THE DRAWINGS

FIG. 1 is a block diagram for explaining a semiconductor memory device according to some example embodiments.

FIG. 2 is a circuit diagram for explaining a semiconductor memory device according to some example embodiments.

FIG. 3 is a schematic layout diagram for explaining a semiconductor memory device according to some example embodiments.

FIGS. 4 and 5 are cross-sectional views taken along line X1-X2 of FIG. 3 and are diagrams illustrating semiconductor memory devices according to some example embodiments.

FIGS. 6 and 7 are cross-sectional views taken along line X1-X2 of FIG. 3 and are diagrams illustrating semiconductor memory devices according to some example embodiments.

FIG. 8 is a perspective view for explaining an electronic system according to some example embodiments.

FIG. 9 is a schematic cross-sectional view taken along line I-I of FIG. 8.

### DETAILED DESCRIPTION

As used herein, although terms such as first and second are used to describe various elements or components, it goes without saying that these elements or components are not limited by these terms. These terms are only used to distinguish a single element or component from other elements or components. Therefore, it goes without saying that a first element or component referred to below may be a second element or component within the technical idea of example embodiments.

It will be understood that when an element such as a layer, film, region, or substrate is referred to as being “on” another element, it may be directly on the other element or intervening elements may also be present. In contrast, when an element is referred to as being “directly on” another element, there are no intervening elements present. It will further be understood that when an element is referred to as being “on” another element, it may be above or beneath or adjacent (e.g., horizontally adjacent) to the other element.

It will be understood that elements and/or properties thereof (e.g., structures, surfaces, directions, or the like), which may be referred to as being “perpendicular,” “parallel,” “coplanar,” or the like with regard to other elements and/or properties thereof (e.g., structures, surfaces, directions, or the like) may be “perpendicular,” “parallel,” “coplanar,” or the like or may be “substantially perpendicular,” “substantially parallel,” “substantially coplanar,” respectively, with regard to the other elements and/or properties thereof.

It will be understood that elements and/or properties thereof may be recited herein as being “the same” or “equal” as other elements, and it will be further understood that elements and/or properties thereof recited herein as being “identical” to, “the same” as, or “equal” to other elements may be “identical” to, “the same” as, or “equal” to or “substantially identical” to, “substantially the same” as or “substantially equal” to the other elements and/or properties thereof. Elements and/or properties thereof that are “substantially identical” to, “substantially the same” as or “substantially equal” to other elements and/or properties thereof will be understood to include elements and/or properties thereof that are identical to, the same as, or equal to the other elements and/or properties thereof within manufacturing tolerances and/or material tolerances. Elements and/or properties thereof that are identical or substantially identical to and/or the same or substantially the same as other elements and/or properties thereof may be structurally the same or substantially the same, functionally the same or substantially the same, and/or compositionally the same or substantially the same.

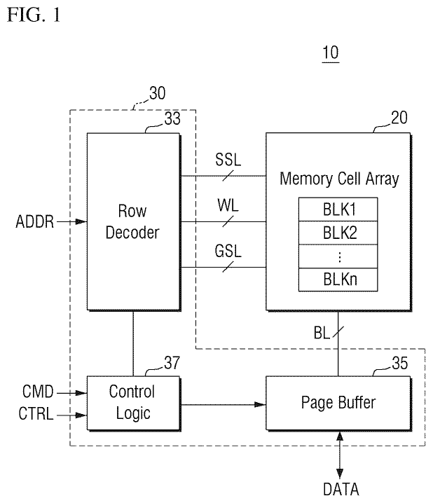

A semiconductor memory device according to some example embodiments will be described below with reference to FIGS. 1 to 9.

FIG. 1 is a block diagram for explaining a semiconductor memory device according to some embodiments.

Referring to FIG. 1, a semiconductor memory device 10 according to some example embodiments includes a memory cell array 20 and a peripheral circuit 30.

The memory cell array 20 may include a plurality of memory cell blocks BLK1 to BLKn. Each of the memory cell blocks BLK1 to BLKn may include a plurality of memory cells. The memory cell array 20 may be connected to the peripheral circuit 30 through a bit line BL, a word line WL, at least one string selection line SSL, and at least one ground selection line GSL. Specifically, the memory cell blocks BLK1 to BLKn may be connected to a row decoder 33 through the word line WL, the string selection line SSL, and the ground selection line GSL. Also, the memory cell blocks BLK1 to BLKn may be connected to the page buffer 35 through the bit line BL.

The peripheral circuit 30 may receive an address ADDR, a command CMD, and a control signal CTRL from outside of the semiconductor memory device 10, and may transmit and receive data DATA to and from an external device of the semiconductor memory device 10. The peripheral circuit 30 may include a control logic 37, a row decoder 33, and a page buffer 35. Although not shown, the peripheral circuit 30 may further include various sub-circuits such as an input/output circuit, a voltage generation circuit that generates various voltages necessary for the operation of the semiconductor memory device 10, and an error correction circuit for correcting error of the data DATA that is read from the memory cell array 20.

The control logic 37 may be connected to the row decoder 33, the input/output circuit, and the voltage generation circuit. The control logic 37 may control the overall operation of the semiconductor memory device 10. The control logic 37 may generate various internal control signals used inside the semiconductor memory device 10 in response to the control signal CTRL. For example, the control logic 37 may adjust the voltage levels provided to the word line WL and the bit line BL when performing a memory operation such as a program operation or an erase operation.

The row decoder 33 may select at least one among the plurality of memory cell blocks BLK1 to BLKn in response to the address ADDR, and may select at least one word line WL, at least one string selection line SSL, and at least one ground selection line GSL of the selected memory cell blocks BLK1 to BLKn. Further, the row decoder 33 may transfer a voltage for performing the memory operation to the word line WL of the selected memory cell blocks BLK1 to BLKn.

The page buffer 35 may be connected to the memory cell array 20 through the bit line BL. The page buffer 35 may operate as a writer driver or a sense amplifier. Specifically, when the program operation is performed, the page buffer 35 may operates as the writer driver to apply a voltage corresponding to the data DATA to be stored in the memory cell array 20 to the bit line BL. On the other hand, when performing the read operation, the page buffer 35 may operate as a sense amplifier to sense the data DATA stored in the memory cell array 20.

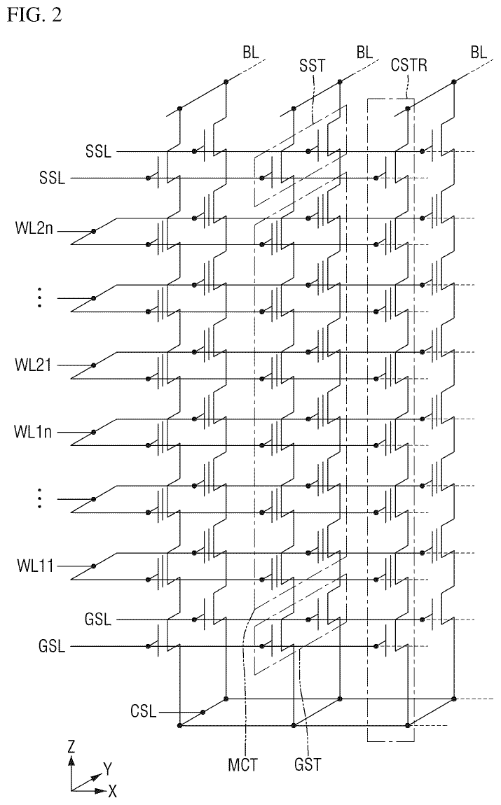

FIG. 2 is an exemplary circuit diagram for explaining a semiconductor memory device according to some example embodiments.

Referring to FIG. 2, the memory cell array (e.g., 20 of FIG. 1) of the semiconductor device according to some example embodiments may include a common source line CSL, a plurality of bit lines BL, and a plurality of cell strings CSTR, but example embodiments are not limited thereto.

The plurality of bit lines BL may be arranged two-dimensionally in a plane including a first direction X and a second direction Y. For example, the bit lines BL may each extend in the second direction Y, be spaced apart from each other, and be arranged along the first direction X. A plurality of cell strings CSTR may be connected in parallel to each bit line BL. The cell strings CSTR may be commonly connected to the common source line CSL. That is, the plurality of cell strings CSTR may be placed between the bit lines BL and the common source line CSL.

Each cell string CSTR may include a ground selection transistor GST connected to the common source line CSL, a string selection transistor SST connected to the bit line BL, and a plurality of memory cell transistors MCT placed between the ground selection transistor GST and the string selection transistor SST. Each memory cell transistor MCT may include a data storage element. The ground selection transistor GST, the string selection transistor SST and the memory cell transistors MCT may be connected in series.

The common source line CSL may be commonly connected to sources of the ground selection transistors GST. Also, the ground selection line GSL, a plurality of word lines WL11 to WL1n and WL21 to WL2n, and the string selection line SSL may be placed between the common source line CSL and the bit line BL. The ground selection line GSL may be used as a gate electrode of the ground selection transistor GST, the word lines WL11 to WL1n and WL21 to WL2n may be used as gate electrodes of the memory cell transistors MCT, and the string selection line SSL may be used as the gate electrode of the string selection transistor SST.

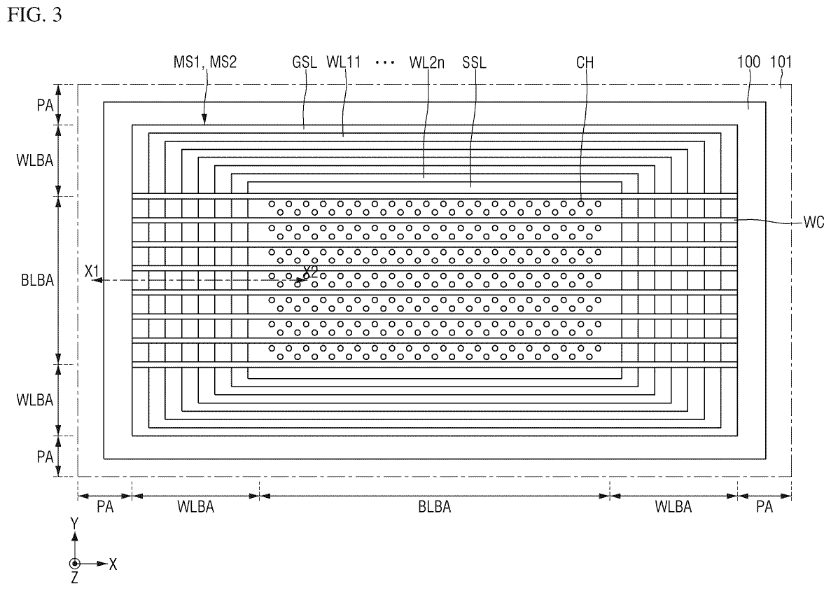

FIG. 3 is a schematic layout diagram for explaining a semiconductor memory device according to some example embodiments.

The semiconductor memory device according to some example embodiments includes a cell structure BLBA, a peripheral circuit structure PERI, and an input/output wiring structure 380, but example embodiments are not limited thereto.

The cell structure BLBA may include a cell substrate 100, an insulating substrate 101, mold structures MS1 and MS2, interlayer insulating films 201 and 301, a channel structure CH, a word line cutting region WC, a bit line BL, a gate contact, a cell wiring structure BL, and an impurity region.

The cell substrate 100 may include, for example, a semiconductor substrate such as a silicon substrate, a germanium substrate or a silicon-germanium substrate. Alternatively, the cell substrates 100 and 310 may include a silicon-on-insulator (SOI) substrate, a germanium-on-insulator (GOI) substrate, and the like. In some example embodiments, the cell substrates 100 and 310 may include polysilicon (poly Si).

In some example embodiments, the cell substrate 100 may have the first conductivity type by including impurities. For example, the cell substrate 100 may include P-type impurities (e.g., boron (B), aluminum (Al), indium (In), gallium (Ga), etc.). Although the following description will be mainly described on the fact that the first conductivity type is the P-type, this is merely an example, and it goes without saying that the first conductivity type may be an N-type.

The cell substrate 100 may include a cell array region BLBA, an extended region WLBA, and a PA (external pad bonding region).

A memory cell array (e.g., 20 of FIG. 1) including a plurality of memory cells may be disposed on the cell array region R1. For example, a channel structure CH, gate electrodes (GSL, WL11 to WL1n, WL21 to WL2n, and SSL), a bit line BL, and the like, which will be described below, may be placed on the cell array region BLBA. In the following description, a surface of the cell substrate 100 on which the memory cell array is placed may be referred to as a first side or a front side (or an upper side, a front side). In contrast, a surface of the cell substrate 100 opposite to the first side (or the front side) of the cell substrate 100 may be referred to as a second side or a back side of the cell substrate 100.

The extended region WLBA may be defined around the cell array region BLBA. For example, the extended region WLBA may surround the cell array region BLBA from a planar point of view. The gate electrodes GSL, WL11 to WL1n, WL21 to WL2n, and SSL, which will be described below, may be stacked stepwise in the extended region WLBA.

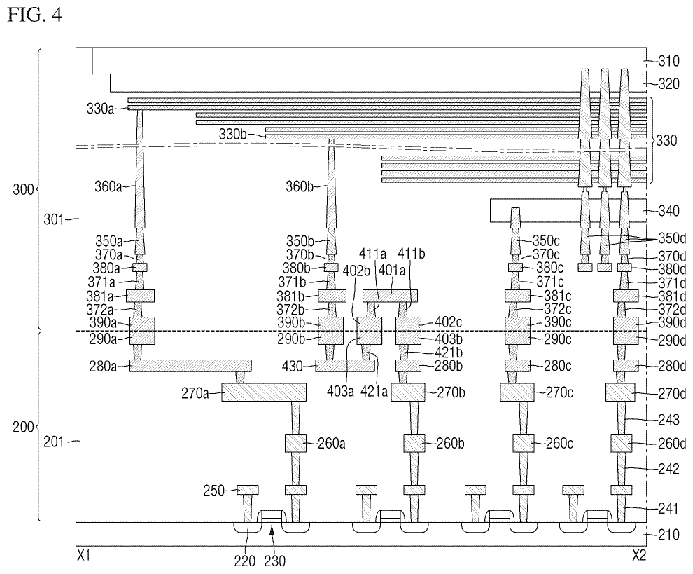

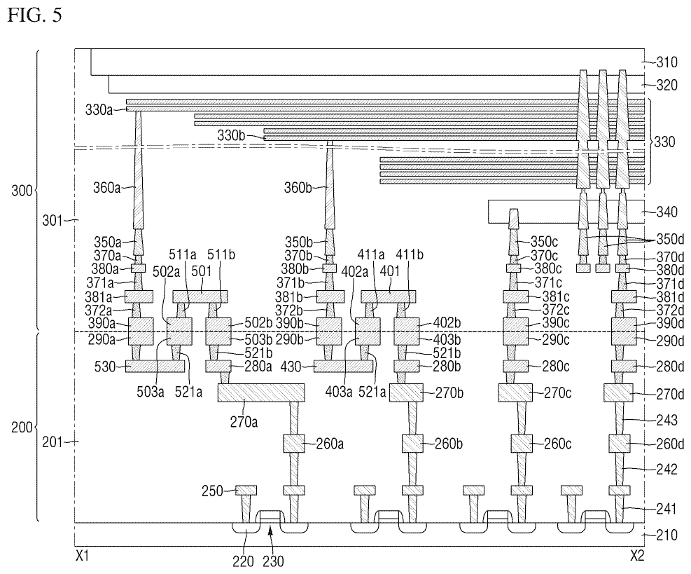

FIGS. 4 and 5 are cross-sectional views taken along X1 and X2 of FIG. 3, showing a semiconductor memory device according to some example embodiments.

Referring to FIGS. 3 to 5, each of the peripheral circuit region 200 and the cell region 300 of the memory device 10 may include an external pad bonding region PA, a word line bonding region WLBA, and a bit line bonding region BLBA, but example embodiments are not limited thereto.

The memory device 10 may have a C2C (chip to chip) structure. The C2C structure may mean a structure in which at least one upper chip including a cell region CELL and a lower chip including a peripheral circuit region PERI are each fabricated, and then, the at least one upper chip and the lower chip are connected to each other in a bonding manner. As an example, the bonding manner may mean a manner of electrically or physically connecting a bonding metal formed on an uppermost metal layer of the upper chip and a bonding metal formed on an uppermost metal layer of the lower chip to each other. For example, when the bonding metals are formed of copper (Cu), the bonding manner may be a Cu—Cu bonding manner. As another example, the bonding metals may also be formed of aluminum (Al) or tungsten (W).

The memory device 10 may include at least one upper chip including the cell region. For example, when the memory device 10 is implemented to include two upper chips, the memory device 10 may be fabricated by connecting a first upper chip including the cell region 300, a second upper chip including a second cell region CELL2, and a lower chip including a peripheral circuit region PERI, and then connecting the first upper chip, the second upper chip, and the lower chip to each other in the bonding manner. The first upper chip may be inverted and connected to the lower chip in the bonding manner, and the second upper chip may also be inverted and connected to the first upper chip in the bonding manner. In the following description, the upper parts and the lower parts of the first and second upper chips are defined on the basis of before the first upper chip and the second upper chip are inverted. That is, the upper part of the lower chip means the upper part defined on the basis of a +Z-axis direction, and the upper parts of each of the first and second upper chips mean the upper parts defined on the basis of a −Z-axis direction. However, this is an example, and only one of the first upper chip and the second upper chip may be inverted and connected in the bonding manner.

The peripheral circuit region 200 may include a first substrate 210, and a plurality of circuit elements 230 disposed on the first substrate 210. An interlayer insulating film 201 including one or more insulating layers may be provided on the plurality of circuit elements 230, and a plurality of metal wirings which connect the plurality of circuit elements 230 may be provided inside the interlayer insulating film 201. For example, the plurality of metal wirings may include first metal wirings (260a, 260b, 260c, and 260d; 260) connected to each of the plurality of circuit elements 120, second metal wirings (270a, 270b, 270c, and 270d; 270) disposed on the first metal wiring 260, and upper metal patterns (280a, 280b, 280c, 280d; 280) disposed on the second metal wiring 270. The plurality of metal wirings may be made up of at least one of various conductive materials. For example, the first metal wiring 260 may be formed of tungsten having a relatively high electrical resistivity, and the second metal wiring 270 and the upper metal pattern 280 may be formed of copper having a relatively low electrical resistivity.

The interlayer insulating film 201 is placed on the first substrate 210, and may include an insulating material such as silicon oxide and silicon nitride.

Each cell region (CELL) 300 may include at least one memory block. The cell region 300 may include a second substrate 310 and a common source line 320. A plurality of word lines 330 may be stacked on the second substrate 310 along a direction (Z-axis direction) perpendicular to the upper side of the second substrate 310. String selection lines and ground selection lines may be placed above and below the word lines 330, and the plurality of word lines 330 may be placed between the string selection lines and the ground selection lines. The second substrate 310 may be made of a variety of materials, and may be a substrate having, for example, a monocrystalline epitaxial layer grown on a silicon substrate, a silicon-germanium substrate, a germanium substrate or a monocrystalline silicon substrate. A plurality of channel structures 350d may be disposed in each of the cell regions 300.

In an example embodiment, the channel structure 350d may be provided in the bit line bonding region BLBA and extend in a direction perpendicular to the upper side of the second substrate 310 to penetrate the word lines 330, the string selection lines, and the ground selection line. The channel structure 350d may include a data storage layer, a channel layer, a buried insulating layer, and the like. The channel layer may be electrically connected to the first metal wiring 380d and the second metal wiring 381d in the bit line bonding region BLBA. For example, the second metal wiring 381d may be a bit line, and may be connected to the channel structure 350d through the first metal wiring 380d. The bit line 380d may extend along the first direction (Y-axis direction) parallel to the upper side of the second substrate 310.

A through electrode THV may be provided in the cell region 300 in the bit line bonding region BLBA. The through electrode THV may penetrate the common source line 320 and the plurality of word lines 330. However, this is an example, and the through electrode THV may further penetrate the second substrate 310. The through electrode THV may include a conductive material. Alternatively, the through electrode THV may include a conductive material surrounded by an insulating material.

Vias (371a, 371b, 371c, and 371d; hereinafter 371, and 372a, 372b, 372c, and 372d; hereinafter 372) may be placed and electrically connected between the metal patterns, and between the metal pattern and the bonding metal pattern.

In the bit line bonding region BLBA, upper metal patterns 280a, 280b, 280c, and 280d are disposed on the uppermost metal layer of the peripheral circuit region 200, and upper metal patterns 381a, 381b, 381c and 381d having the same shape as the upper metal patterns 280a, 280b, 280c and 280d may be disposed on the uppermost metal layer of the cell region 300. The upper metal patterns 381a, 381b, 381c and 381d of the cell region 300 and the upper metal patterns 280a, 280b, 280c and 280d of the peripheral circuit region 200 may be electrically connected to each other in the bonding manner. In the bit line bonding region BLBA, the bit line 380d may be electrically connected to page buffers included in the peripheral circuit region 200. For example, some of the circuit element 230 of the peripheral circuit region 200 may provide page buffers, and the bit line 380d may be electrically connected to the circuit elements 230 that provide the page buffer through the upper bonding metals 390a, 390b, 390c, and 390d of the cell region 300 and the upper bonding metals 290a, 290b, 290c, and 290d of the peripheral circuit region 200.

FIGS. 4 and 5 are cross-sectional views taken along line X1-X2 of FIG. 3 and are diagrams illustrating semiconductor memory devices according to some example embodiments.

Subsequently, referring to FIG. 4, in the word line bonding region WLBA, the word lines 330 of the cell region 300 may extend along the second direction (X-axis direction) parallel to the upper side of the second substrate 310, and may be connected to a plurality of cell contact plugs (360a, 360b; 360) disposed in a vertical direction. First metal wirings (380a, 380b, 380c and 380d; 380) and second metal wirings 381a, 381b, 381c and 381d may be connected sequentially above the cell contact plugs 360 connected to the word lines 330. The cell contact plugs 360 may be connected to the peripheral circuit region 200 through the upper bonding metal 390 of the cell region 300 and the upper bonding metal 290 of the peripheral circuit region 200 in the word line bonding region WLBA.

The gate electrodes GSL, WL11 to WL1n, WL21 to WL2n, and SSL may be stacked stepwise in the extended region WLBA of the cell region 300. However, as the number of word line electrodes stacked in a stepwise manner gradually increases, the distance to the bonding metal 390 for being connected to the circuit elements 230 may change depending on the position of the word line electrodes. For example, a highest electrode WL2n of the word line electrodes 330 may have a different distance to the circuit element 230 connected to the row decoder from a lowest electrode WL21. In the extended region WLBA, the wiring resistance of the gate electrodes vary depending on the distance to the circuit element 230 for each position. When the difference in wiring resistance increases as the number of stacked layers increases, the performance may be influenced when the memory cell access of the memory device 10 operates

Cell contact plugs (360a, 360b; hereinafter 360) may be electrically connected to row decoders included in the peripheral circuit region 200. For example, some of the circuit elements 230 of the peripheral circuit region 200 provide a row decoder, and the cell contact plugs 360 may be electrically connected to the circuit elements 230 that provide the row decoder through the upper bonding metal 390 of the cell region 300 and the upper bonding metal 290 of the peripheral circuit region 200. In an example embodiment, an operating voltage of the circuit elements 230 that provide the row decoder may be different than the operating voltage of the circuit elements 230 that provide the page buffer. For example, the operating voltage of the circuit elements 230 that provide the page buffer may be higher than the operating voltage of the circuit elements 230 that provide the row decoder.

In the word line bonding region WLBA, an upper bonding metal 390 may be disposed in the cell region 300, and an upper bonding metal 290 may be disposed in the peripheral circuit region 200. The upper bonding metal 390 of the cell region 300 and the upper bonding metal 290 of the peripheral circuit region 200 may be electrically connected to each other in the bonding manner. The upper bonding metal 390 and the upper bonding metal 290 may be disposed of aluminum, copper, tungsten, or the like.

According to some example embodiments, in the word line bonding region WLBA, the cell region 300 and the peripheral circuit region 200 may further include a plurality of dummy bonding metals (402b, 402c; hereinafter 402, and 403a, 403b; hereinafter 403). The dummy bonding metals 402 and 403 may be electrically connected to at least some of the plurality of cell contact plugs 360 to form a bypass path. For convenience of explanation, although the cell contact plug 360b connected by the bypass path is called a bypass cell contact plug, and the cell contact plug 360a connected by one bonding metal pair 390 to 290 without a bypass path is called a normal cell contact plug, the scope of example embodiments is not limited to this name.

For example, referring to FIG. 4, the bypass cell contact plug 360b is connected to the circuit element 230 through two second metal wirings 381b and 401a of the cell region 300, three bonding metal pairs 390b-290b, 402b-403a, and 402c-403b, and the two second metal wirings 430 and 280b of the peripheral circuit region 200. The normal cell contact plug 360a is connected to the circuit element 230 through the single second metal wiring 381 of the cell region 300, the single upper bonding metal pairs 390a and 290a, and the single second metal wiring 280a of the peripheral circuit region 200. That is, the bypass path to which the bypass cell contact plug 360b is formed by a path that bypasses in an S shape bent twice, by including the two dummy bonding metal pairs 402b-403a, and 402c-403b, the dummy metal wiring 401a of the cell region 300, and the dummy metal wiring 430 of the peripheral circuit region 200.

The word line electrode 330b connected to the bypass cell contact plug 360b and the word line electrode 330a connected to the normal cell contact plug 360a are matched to correspond to each other in connection wiring resistance due to the bypass path. Accordingly, performance reliability of the memory device 10 is improved, regardless of the position of the word line electrode. In this specification, the expression “connection wiring resistances are matched to correspond to each other” means that the resistance components of the connection wirings are equal or within an equal error range in an example embodiment. Alternatively, in another example embodiment, it may mean that the resistance components of the connection wirings are designed to have a preset ratio to each other. That is, the resistance component of the first connection wiring having the first bypass path may have a preset ratio of 1:k (at this time, k is a rational number equal to or greater than 0) with the resistance component of the second connection wiring.

According to some example embodiments, the bypass path may be formed for each cell contact plug of the entire word line electrode, or may be formed at regular intervals in consideration of the stacked form of the word line electrode. Also, the bypass path may be formed to include three or more bonding metal pairs depending on the wiring resistance difference from the reference cell contact plug.

For example, on the basis of the wiring resistance of the cell contact plug connected to the lowest word line electrode WL1, a first bypass path of a m-th stacked word line electrode WLm may be formed by a path that bypasses in an S shape bent twice, by including two dummy bonding metal pairs 402b-403a and 402c-403b, the dummy metal wiring 401a of the cell region 300, and the dummy metal wiring 430 of the peripheral circuit region 200, as shown in FIG. 4. The second bypass path of a n-th (n is a natural number larger than m) stacked word line electrode WLn may be formed by a path that bypasses in an S shape that is bent four times in the vertical direction and overlaps, by including four dummy bonding metal pairs, the two dummy metal wirings of the cell region 300, and the two dummy metal wirings of the peripheral circuit region 200.

For example, referring to FIG. 5, the first bypass cell contact plug 360a is connected to the circuit element 230 through two second metal wirings 381a and 501 of the cell region 300, three bonding metal pairs 390a-290a, 502a-503a, and 502b-503b, and the two second metal wirings 530 and 280a of the peripheral circuit region 200. The first bypass path to which the first bypass cell contact plug 360a is connected is formed by a path that bypasses in an S shape bent twice in the vertical direction, by including two dummy bonding metal pairs 502a-503a and 502b-503b, the dummy metal wiring 501 of the cell region 300, and the dummy metal wiring 530 of the peripheral circuit region 200.

The second bypass cell contact plugs 360b is connected to the circuit element 230 through two second metal wirings 381b and 401a of the cell region 300, three bonding metal pairs 390b-290b, 402b-403a, and 402c-403b, and two second metal wirings 430 and 280b of the peripheral circuit region 200. The second bypass path to which the second bypass cell contact plug 360b is connected is formed by a path that bypasses in an S shape bent twice in the vertical direction, by including the two dummy bonding metal pairs 402b-403a and 402c-403b, the dummy metal wiring 401a of the cell region 300, and the dummy metal wiring 430 of the peripheral circuit region 200.

At this time, the dummy metals 501 and 530 of the first bypass path may have different lengths from the dummy metals 401 and 430 of the second bypass path. For example, the dummy metals 501 and 530 may be shorter in length in the X direction and/or Y direction than the dummy metals 401 and 430 such that the resistance of the first bypass path is less than the resistance of the second bypass path.

The dummy bonding metal 402 of the cell region 300 and the dummy bonding metal 403 of the peripheral circuit region 200 may be formed of the same material through the same process as the upper bonding metals 390 and 290. The dummy bonding metal 402 of the cell region 300 and the dummy bonding metal 403 of the peripheral circuit region 200 may be electrically connected to each other in the bonding manner.

Although not shown, common source line contact plugs may be placed in the external pad bonding region PA. The common source line contact plugs may be formed of a conductive material such as metal, metal compound or doped polysilicon. The common source line contact plug of the cell region 300 may be electrically connected to the common source line 320. A first metal wiring 380 and a second metal wiring 381 may be sequentially stacked on the common source line contact plug of the cell region 300.

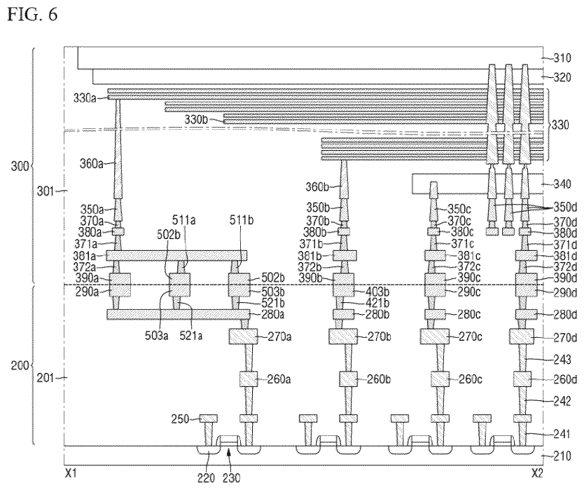

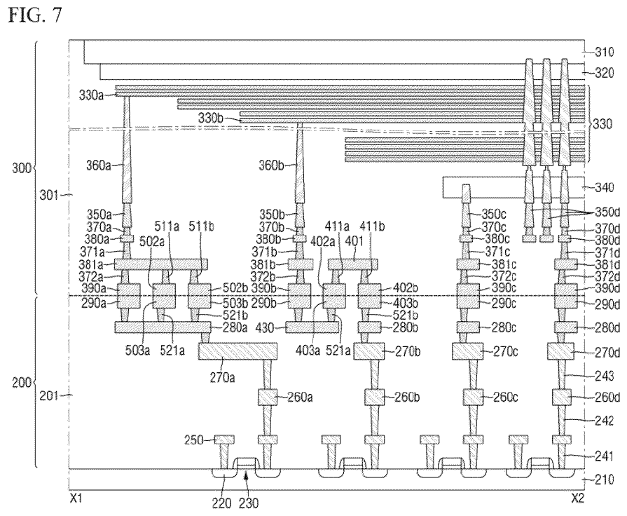

FIGS. 6 and 7 are cross-sectional views taken along X1 and X2 of FIG. 3, showing a semiconductor memory device according to some example embodiments.

Referring to FIGS. 3, 6 and 7, each of the peripheral circuit region 200 and the cell region 300 of the memory device 10 may include an external pad bonding region PA, a word line bonding region WLBA, and a bit line bonding region BLBA. For convenience of explanation, repeated explanation of contents of FIGS. 4 and 5 will not be provided.

The memory device 10 may have a chip-to-chip (C2C) structure which includes at least one upper chip including a cell region CELL, and a lower chip including a peripheral circuit region PERI. For example, when the memory device 10 is implemented to include two upper chips, the memory device 10 may be fabricated, by fabricating each of a first upper chip including the cell region 300, a second upper chip including the second cell region CELL2, and the lower chip including the peripheral circuit region PERI, and then by connecting the first upper chip, the second upper chip, and the lower chip to each other in the bonding manner.

The peripheral circuit region 200 may include a first substrate 210, a plurality of circuit elements 230 disposed on the first substrate 210, and a plurality of metal wirings for connecting the plurality of circuit elements 230. For example, the plurality of metal wirings may include first metal wirings (260a, 260b, 260c, and 260d; 260) connected to each of the plurality of circuit elements 120, second metal wirings (270a, 270b, 270c, 270d; 270) disposed on the first metal wiring 260, and third metal wirings (280a, 280b, 280c, 280d; 280) disposed on the second metal wiring 270.

In the bit line bonding region BLBA, upper metal patterns 280a, 280b, 280c, and 280d are disposed on the uppermost metal layer of the peripheral circuit region 200, and upper metal patterns 381a, 381b, 381c and 381d having the same shape as the upper metal patterns 280a, 280b, 280c and 280d may be disposed on the uppermost metal layer of the cell region 300. The upper metal patterns 381a, 381b, 381c and 381d of the cell region 300 and the upper metal patterns 280a, 280b, 280c and 280d of the peripheral circuit region 200 may be electrically connected to each other in the bonding manner. In the bit line bonding region BLBA, the bit line 380d may be electrically connected to page buffers included in the peripheral circuit region 200. For example, some of the circuit elements 230 of the peripheral circuit region 200 may provide a page buffer, and the bit line 380d may be electrically connected to the circuit elements 230 that provide the page buffer through the upper bonding metals 390a, 390b, 390c, and 390d of the cell region 300 and the upper bonding metals 290a, 290b, 290c, and 290d of the peripheral circuit region 200.

FIGS. 6 and 7 are cross-sectional vies taken along line X1-X2 of FIG. 3 and are diagrams illustrating semiconductor memory devices according to some example embodiments. Subsequently, referring to FIG. 6, cell contact plugs (360a, 360b; hereinafter 360) may be electrically connected to the row decoder included in the peripheral circuit region 200. For example, some of the circuit elements 230 of the peripheral circuit region 200 provide a row decoder, and the cell contact plugs 360 may be electrically connected to the circuit elements 230 that provide the row decoder through the upper bonding metal 390 of the cell region 300 and the upper bonding metal 290c of the peripheral circuit region 200.

In the word line bonding region WLBA, the upper bonding metal 390 may be disposed in the cell region 300, and the upper bonding metal 290 may be disposed in the peripheral circuit region 200. According to some example embodiments, in the word line bonding region WLBA, the cell region 300 and the peripheral circuit region 200 may further include a plurality of dummy bonding metals (502b, 502c; hereinafter 502, and 503a, 503b; hereinafter 503). The upper bonding metals 390 and 502 of the cell region 300 and the upper bonding metals 290 and 503 of the peripheral circuit region 200 may be electrically connected to each other in the bonding manner.

The dummy bonding metals 502 and 503 may be electrically connected to at least some of the plurality of cell contact plugs 360 to form a shortcut path. For convenience of explanation, although the cell contact plug 360a connected by the shortcut path is called a shortcut cell contact plug, and the cell contact plug 360b connected by one bonding metal pair 390-290 without a bypass path is called a normal cell contact plug, the scope of the invention is not limited to this name.

For example, the shortcut cell contact plug 360a is connected to the circuit element 230 through one long second metal wiring 381a of the cell region 300, three bonding metal pairs 390a-290a, 502a-503a, and 502b-503b, and one long second metal wiring 280a of the peripheral circuit region 200. The normal cell contact plug 360a is connected to the circuit element through one second metal wiring 381b of the cell region 300, one upper bonding metal pair 390b, 290b, and one second metal wiring 280b of the peripheral circuit region 200. That is, the shortcut path to which the shortcut cell contact plug 360a is connected is formed by a path that is connected in parallel between the second metal wirings 381a and 280a in the form of a ladder between the cell region 300 and the peripheral circuit region 200, by including the three bonding metal pairs 390a-290a, 502a-503a, and 502b-503b, the second metal wiring 381a of the cell region 300, and the second metal wiring 280a of the peripheral circuit region 200.

Due to the shortcut path, the connection wiring resistance of the word line electrode 330a connected to the shortcut cell contact plug 360a may decrease. Accordingly, the word line electrode 330a connected to shortcut cell contact plug 360a and the word line electrode 330b connected to the normal cell contact plug 360a are matched to correspond to each other in connection wiring resistance. Accordingly, performance reliability of the memory device 10 is improved, regardless of the position of the word line electrode. In this specification, the expression “connection wiring resistances are matched to correspond to each other” means that the resistance components of the connection wirings are equal or within an equal error range in an example embodiment. Alternatively, in another example embodiment, it may mean that the resistance components of the connection wirings are designed to have a preset ratio to each other. That is, the resistance component of the first connection wiring having the first bypass path may have a preset ratio of 1:k (at this time, k is a rational number equal to or greater than 0) with the resistance component of the second connection wiring.

According to some example embodiments, the shortcut path may be formed at regular intervals in consideration of the stacked form of the word line electrode. Also, the shortcut path may be formed to include three or more bonding metal pairs, depending on the wiring resistance difference from the reference cell contact plug.

For example, on the basis of the wiring resistance of the cell contact plug connected to the lowest word line electrode WL1, a first shortcut path of the m-th stacked word line electrode WLm may be formed in the form of a ladder including three bonding metal pairs as shown in FIG. 6. Further, a second bypass path of the n-th (n is a natural number greater than m) stacked word line electrode WLn may be formed in the form of a ladder including five dummy bonding metal pairs.

For example, referring to FIG. 7, the memory device 10 may be implemented to include both the bypass path and the shortcut path.

For example, at least one of the plurality of cell contact plugs 360 of the memory device 10 may be implemented as a bypass cell contact plug 360b. The bypass cell contact plug 360b is connected to the circuit element through two second metal wirings 381b and 401a of the cell region 300, three bonding metal pairs 390b-290b, 402b-403a, and 402c-403b, and two second metal wirings 430 and 280b of the peripheral circuit region 200. The normal cell contact plug 360a is connected to the circuit element through one second metal wiring 381 of the cell region 300, one upper bonding metal pair 390a and 290a, and one second metal wiring 280a of the peripheral circuit region 200. That is, the bypass path to which the bypass cell contact plug 360b is connected is formed by a path that bypasses in an S shape bent twice, by including the two dummy bonding metal pairs 402b-403a and 402c-403b, the dummy metal wiring 401a of the cell region 300, and the dummy metal wiring 430 of the peripheral circuit region 200.

For example, at least one of the plurality of cell contact plugs 360 of the memory device 10 may be implemented as the shortcut cell contact plug 360a. The shortcut path to which the shortcut cell contact plug 360a is formed by a path that is connected in parallel between the second metal wirings 381a and 280a in the form of a ladder between the cell region 300 and the peripheral circuit region 200, by including the three bonding metal pairs 390a-290a, 502a-503a, and 502b-503b, the second metal wiring 381a of the cell region 300, and the second metal wiring 280a of the peripheral circuit region 200.

That is, on the basis of the connection wiring resistance between the normal cell contact plug 360 and the word line electrode 330, which is set as a reference, the path of the bypass path is formed to be longer to increase the resistance value in comparison with the connection wiring resistance of the cell contact plug, the metal wiring, and the bonding metal pairs that are connected vertically. The shortcut path utilizes the parallel connection of metal wirings to reduce the resistance value in comparison with the connection wiring resistance of the cell contact plug, the metal wiring and the bonding metal pair that are connected vertically.

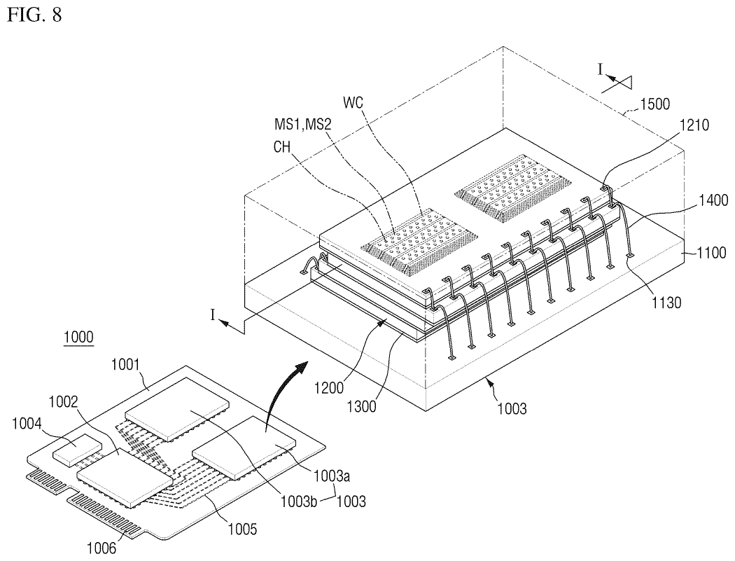

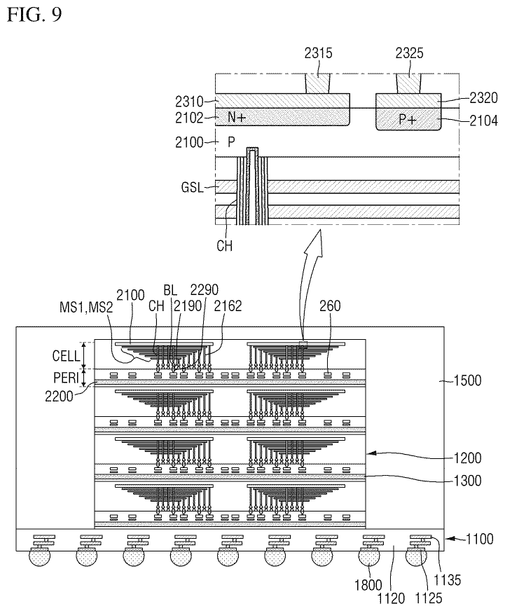

FIG. 8 is a perspective view for explaining an electronic system according to some example embodiments. FIG. 9 is a schematic cross-sectional view taken along line I-I of FIG. 8. For convenience of explanation, repeated parts of contents explained above using FIGS. 1 to 7 will be briefly explained or omitted.

Referring to FIGS. 8 and 9, an electronic system according to some example embodiments may include a main board 1001, a main controller 1002 mounted on the main board 1001, one or more semiconductor packages 1003, and a DRAM 1004. The semiconductor package 1003 and the DRAM 1004 may be connected to the main controller 1002 by wiring patterns 1005 disposed on the main board 1001.

The main board 1001 may include a connector 1006 including a plurality of pins coupled to an external host. In the connector 1006, the number and placement of the plurality of pins may vary depending on the communication interface between the electronic system 1000 and the external host. In some example embodiments, the electronic system 1000 may communicate with the external host according to any one of interfaces such as M-Phy for USB (Universal Serial Bus), PCI-Express (Peripheral Component Interconnect Express), SATA (Serial Advanced Technology Attachment), and UFS (Universal Flash Storage). In some example embodiments, the electronic system 1000 may operate by power supplied from the external host through the connector 1006. The electronic system 1000 may further include a PMIC (Power Management Integrated Circuit) that distributes the power supplied from the external host to the main controller 1002 and the semiconductor package 1003.

The main controller 1002 may record data in the semiconductor package 1003 or read data from the semiconductor package 1003, and may improve the operating speed of the electronic system 1000.

The DRAM 1004 may be a buffer memory for relieving a speed difference between the semiconductor package 1003, which is a data storage space, and the external host. The DRAM 1004 included in the electronic system 1000 may also operate as a kind of cache memory, and may also provide a space for temporarily storing data in the control operation on the semiconductor package 1003. When the DRAM 1004 is included in the electronic system 1000, the main controller 1002 may further include a DRAM controller for controlling the DRAM 1004, in addition to a NAND controller for controlling the semiconductor package 1003.

The semiconductor package 1003 may include a first semiconductor package 1003a and a second semiconductor package 1003b that are spaced apart from each other. The first semiconductor package 1003a and the second semiconductor package 1003b may each be a semiconductor package that includes a plurality of semiconductor chips 1200. The first semiconductor package 1003a and the second semiconductor package 1003b may each include a package substrate 1100, semiconductor chips 1200 on the package substrate 1100, adhesive layers 1300 placed on the lower sides of each of the package chips 1200, a connecting structure 1400 for electrically connecting the semiconductor chips 1200 and the package substrate 1100, and a molding layer 1500 that covers the semiconductor chips 1200 and the connecting structure 1400 on the package substrate 1100.

The package substrate 1100 may be a printed circuit board that includes upper pads 1130. Each semiconductor chip 1200 may include an I/O pad 1210.

In some example embodiments, the connecting structure 1400 may be a bonding wire that electrically connects the I/O pad 1101 and the package upper pads 1130. Therefore, in each of the first semiconductor package 1003a and the second semiconductor package 1003b, the semiconductor chips 1200 may be electrically connected to each other in a bonding wire manner, and may be electrically connected to the package upper pads 1130 of the package substrate 1100. In some example embodiments, in each of the first semiconductor package 1003a and the second semiconductor package 1003b, the semiconductor chips 1200 may be electrically connected to each other by a connecting structure including a through electrode (Through Silicon Via, TSV) instead of the connecting structure 1400 of a bonding wire manner.

In some example embodiments, the main controller 1002 and the semiconductor chips 1200 may also be included in a single package. In some example embodiments, the main controller 1002 and the semiconductor chips 1200 are mounted on a separate interposer substrate different from the main board 1001, and the main controller 1002 and the semiconductor chips 1200 may also be connected to each other by the wiring disposed on the interposer substrate.

In some example embodiments, the package substrate 1100 may be a printed circuit board. The package substrate 1100 may include a package substrate body portion 1120, package upper pads 1130 placed on an upper side of the package substrate body portion 1120, lower pads 1125 placed on a lower side of the package substrate body portion 1120 or exposed through the lower side, and inner wirings 1135 that electrically connect the upper pads 1130 and the lower pads 1125 inside the package substrate body portion 1120. The upper pads 1130 may be electrically connected to the connecting structure 1400. The lower pads 1125 may be connected to the wiring patterns 1005 of the main board 1001 of the electronic system 1000 through conductive connections 1800, as in FIG. 8.

In the electronic system according to some example embodiments, each of the semiconductor chips 1200 may include the semiconductor memory device described above using FIGS. 1 to 7. For example, each of the semiconductor chips 1200 may include a peripheral circuit structure PERI and a cell structure BLBA stacked on the peripheral circuit structure PERI. As an example, the peripheral circuit structure PERI may include the peripheral circuit board 210 and the peripheral circuit wiring structure described above using FIGS. 3 to 7. Further, as an example, the cell structure BLBA may include the cell substrate 300, the mold structures MS1 and MS2, the channel structure CH, the bit line BL, the gate contact, the first impurity region, the second impurity region, the source plate, the source contact, the conductive pad, and the erase control contact explained above using FIGS. 3 to 7. The peripheral circuit structure PERI and the cell structure BLBA may be bonded to each other through the first bonding metal and the second bonding metal.

One or more of the elements disclosed above may include or be implemented in one or more processing circuitries such as hardware including logic circuits; a hardware/software combination such as a processor executing software; or a combination thereof. For example, the processing circuitries more specifically may include, but is not limited to, a central processing unit (CPU), an arithmetic logic unit (ALU), a digital signal processor, a microcomputer, a field programmable gate array (FGPA), a System-on-Chip (SoC), a programmable logic unit, a microprocessor, application-specific integrated circuit (ASIC), etc.

Although some example embodiments of inventive concepts have been described above with reference to the accompanying drawings, those skilled in the art will appreciate that inventive concepts may be embodied in other specific forms without changing the technical spirit or essential features of inventive concepts. Accordingly, the above-described example embodiments should be understood in all respects as illustrative and not restrictive.

1. A semiconductor memory device comprising:
a cell region on a cell substrate, and a peripheral circuit region on a peripheral circuit board and connected to the cell region in a bonding manner,
wherein the cell region includes
a plurality of gate electrodes sequentially stacked on a first side of the cell substrate;
a first bypass cell contact plug extended in a vertical direction in an extended region and connected to a first gate electrode of the plurality of gate electrodes;
a normal cell contact plug extended in the vertical direction in the extended region and connected to a second gate electrode of the plurality of gate electrodes;
a first metal wiring electrically connected to the first bypass cell contact plug; and
a second metal wiring on the first metal wiring and electrically connected to the first metal wiring,
wherein the peripheral circuit region includes
a plurality of circuit elements on the peripheral circuit board;
a third metal wiring on a first circuit element of the plurality of circuit elements and electrically connected to the first circuit element; and
a fourth metal wiring on the third metal wiring and electrically connected to the third metal wiring,
wherein the second metal wiring are connected with the fourth metal wiring through a first bypass path including a plurality of bonding metal pairs.

2. The semiconductor memory device of claim 1,
wherein a wiring resistance between the first bypass cell contact plug and the first circuit element corresponds to a wiring resistance between the normal cell contact plug and a second circuit element of the plurality of circuit elements.

3. The semiconductor memory device of claim 1,
wherein the first bypass path comprises:
a first dummy metal wiring on the same layer as the second metal wiring;
a first bonding metal on the second metal wiring; and
first and second dummy bonding metals on the first dummy metal wiring to be spaced apart from each other.

4. The semiconductor memory device of claim 3,
wherein the first bypass path comprises:
a second dummy metal wiring on the same layer as the third metal wiring;
a second bonding metal on the third metal wiring; and
third and fourth dummy bonding metals on the second dummy metal wiring to be spaced apart from each other.

5. The semiconductor memory device of claim 4,
wherein the first bypass path is arranged by connecting the second metal wiring, the first bonding metal, the second dummy metal wiring, the first and third dummy bonding metals, the first dummy metal, the second and fourth dummy bonding metals, and the fourth metal wiring through a plurality of vias.

6. The semiconductor memory device of claim 1,
wherein the first bypass path is connected in an S shape that is bent twice or more in a vertical direction between the second metal wiring and the fourth metal wiring.

7. A semiconductor memory device comprising:
a plurality of gate electrodes stacked on a cell substrate in a vertical direction;
a plurality of cell contact plugs in the vertical direction and have one end connected to each of the plurality of gate electrodes;
a plurality of first metal wirings on the other end of the cell contact plug and connected to each of the plurality of cell contact plugs;
a plurality of second metal wirings on the first metal wirings and each electrically connected to the first metal wirings;
a plurality of first bonding metals on the second metal wirings;
a plurality of first dummy bonding metals in the same layer as the first bonding metals;
a plurality of circuit elements on a peripheral circuit board;
a plurality of third metal wirings on the plurality of circuit elements and each connected to the plurality of circuit elements;
a plurality of fourth metal wirings on the third metal wirings and each electrically connected to the third metal wirings;
a plurality of second bonding metals on the fourth metal wirings, each electrically connected to the fourth metal wiring, and each bonded to the plurality of first bonding metals; and
a plurality of second dummy bonding metals in the same layer as the second bonding metals,
wherein at least one first bonding metal and at least one second bonding metal are electrically connected through the plurality of first dummy bonding metals and the plurality of second dummy bonding metals.

8. The semiconductor memory device of claim 7, further comprising:
at least one first dummy metal wiring on the same layer as the second metal wiring; and
at least one second dummy metal wiring on the same layer as the third metal wiring.

9. The semiconductor memory device of claim 8,
wherein a first cell contact plug of the plurality of cell contact plugs is connected between the first bonding metal and the second bonding metal by a first bypass path, and
the first bypass path includes two second dummy bonding metals, the second dummy metal wiring, two first dummy bonding metals, and the first dummy metal wiring.

10. The semiconductor memory device of claim 8,
wherein a second cell contact plug of the plurality of cell contact plugs is connected between the first bonding metal and the second bonding metal by a second bypass path, and
the second bypass path includes four second dummy bonding metals, the second dummy metal wiring, four first dummy bonding metals, and two first dummy metal wirings.

11. The semiconductor memory device of claim 10,
wherein a wiring resistance of a first cell contact plug of the plurality of cell contact plugs connected by a first bypass path corresponds to a wiring resistance of the second cell contact plug connected by the second bypass path.

12. A semiconductor memory device comprising:
a plurality of gate electrodes stacked on a cell substrate in a vertical direction;
a plurality of cell contact plugs which extend in the vertical direction and have one end connected to each of the plurality of gate electrodes;
a plurality of first metal wirings on the other end of the cell contact plug and connected to each of the plurality of cell contact plugs;
a plurality of second metal wirings on the first metal wirings and electrically connected to each of the first metal wirings;
a plurality of circuit elements on a peripheral circuit board;
a plurality of third metal wirings on the plurality of circuit elements and each connected to the plurality of circuit elements;
a plurality of fourth metal wirings on the third metal wirings and each electrically connected to the third metal wirings; and
a plurality of bonding metal pairs on the second and fourth metal wirings,
wherein each wiring resistance electrically connected from the plurality of cell contact plugs to the plurality of circuit elements is uniform.

13. The semiconductor memory device of claim 12, further comprising:
a plurality of dummy bonding metal pairs on the same layer as the bonding metal pairs and electrically connected to at least one of the plurality of first bonding metals and at least one of the plurality of second bonding metals.

14. The semiconductor memory device of claim 13, further comprising:
at least one first dummy metal wiring on the same layer as the second metal wiring; and
at least one second dummy metal wiring on the same layer as the third metal wiring.

15. The semiconductor memory device of claim 14,
wherein any one of the first bonding metals is connected in series through the first dummy metal wiring, the dummy bonding metal pair, and the second dummy metal wiring, and is electrically connected any one of the second bonding metals.

16. The semiconductor memory device of claim 14,
wherein at least one first bonding metal is electrically connected to at least one second bonding metal through at least two first dummy metal wirings, at least three dummy bonding metal pairs, and at least two second dummy metal wirings.

17. The semiconductor memory device of claim 12,
wherein wiring resistances between the plurality of cell contact plugs and the plurality of circuit elements are set to correspond to each other based of a length of a bypass path passing through at least two dummy bonding metal pairs.

18. The semiconductor memory device of claim 17,
wherein a first bypass path which electrically connects between a first cell contact plug of the plurality of cell contact plugs and a first circuit element of the plurality of circuit elements is different in length from a second bypass path which electrically connects between a second cell contact plug of the plurality of cell contact plugs and a second circuit element of the plurality of circuit elements.

19. The semiconductor memory device of claim 18,
wherein the first cell contact plug is connected between the first bonding metal and the second bonding metal by the first bypass path, and
the first bypass path includes two dummy bonding metal pairs, a first dummy metal wiring, and a second dummy metal wiring.

20. The semiconductor memory device of claim 18,
wherein the second cell contact plug is connected between the first bonding metal and the second bonding metal by the second bypass path, and
the second bypass path includes two first dummy metal wirings, four dummy bonding metal pairs, and two second dummy metal wirings.

21. (canceled)
